(19) United States
(12) Patent Application Publication
(10) Pub. No.: US 2008/0317965 A1
(43) Pub. Date: Dec. 25, 2008

(54) Plasma processing apparatus and method

(75) Inventors: Gil Su Son, Daegu (KR); Doug Yong Sung, Suwon-si (KR); Tae Yong Kwon, Suwon-si (KR); Kyung Chun Lim, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 12/081,408

(22) Filed: Apr. 15, 2008

(30) Foreign Application Priority Data
Jun. 19, 2007 (KR) 10-2007-59805

(51) Int. Cl. C23C 14/32; C23F 1/00

(52) U.S. Cl. 427/446; 216/79; 216/67; 156/345.43; 204/298.02

(57) ABSTRACT

The plasma processing apparatus for processing a semiconductor substrate using plasma and a method thereof can maintain a steady state simultaneously while maximizing a plasma electron density. The plasma processing apparatus includes: a chamber which generates plasma to process a semiconductor substrate; upper and lower electrodes arranged in the chamber; a DC power-supply unit which applies a DC voltage to either one of the upper and lower electrodes; and a controller which adjusts a power ratio of the DC voltage applied from the DC power-supply unit to either one of the upper and lower electrodes. As a result, the apparatus certainly confines electrons, so that the electrodes are not emitted from the plasma, resulting in a maximized plasma electron density.

### CROSS-REFERENCE TO RELATED APPLICATIONS

This application claims the benefit of Korean Patent Application No. 2007-0059805, filed on Jun. 19, 2007 in the Korean Intellectual Property Office, the disclosure of which is incorporated herein by reference.

### BACKGROUND

1. Field

The present invention relates to a method for manufacturing a semiconductor using plasma, and more particularly to a plasma processing apparatus and method for maximizing a plasma electron density to increase a semicircular fabrication speed.

2. Description of the Related Art

Generally, the semiconductor fabrication process has widely used a plasma processing apparatus for etching or depositing a semiconductor substrate using the plasma. A variety of plasma processing apparatuses have been widely used for the plasma processing apparatus. A representative example of the plasma processing apparatus is a Capacitive Coupled Plasma (CCP) processing apparatus.

The CCP processing apparatus arranges a couple of parallel flat electrodes (i.e., upper and lower electrodes) in a chamber of a vacuum status, provides the chamber with the processing gas simultaneously while applying a radio frequency (RF) power to either one of the electrodes, so that it forms a RF electric field between the electrodes. The gas of the chamber is excited into a plasma status by the RF electric field, the CCP processing apparatus etches (or deposits) a semiconductor film located at the other electrode using ions and electrons generated from the plasma, in such a way that the plasma etching (or deposition) is conducted to process the semiconductor substrate.

The plasma processing apparatus generally uses a high-power RF power-supply unit for providing the RF power to the electrodes so as to allow the gas to be excited into the plasma status in the chamber. In this case, a use frequency and a power of the RF power-supply unit affect the processing characteristics.

Although the initial technology has used only one RF power-supply unit, the number of characteristics requisite for the semiconductor fabrication process increases in proportion to the semiconductor integration degree. In order to solve this problem, a variety of methods employing two frequencies have been developed. Recently, a variety of processing devices employing at least three frequencies have been developed.

FIG. 1 is a conceptual diagram illustrating the RF power-supply unit system for use in the plasma processing apparatus disclosed in U.S. Pat. No. 6,423,242.

Referring to FIG. 1, the RF power-supply unit connects two RF power-supply units 7 and 9 to upper and lower electrodes 3 and 5 arranged in parallel in a chamber 1, respectively, so that two different RF powers (i.e., a source RF power and a bias RF power) are applied to the upper and lower electrodes, respectively. A low frequency from among the supplied RF powers adjusts the ion energy from among construction elements of the plasma, and a high frequency adjusts ion density so that the high frequency can contribute to the high etching rate (or deposition rate).

The RF power-supply system employing two different frequencies requires a higher plasma electron density as the semiconductor fabrication process requires a higher processing speed, so that devices of the high frequency have been developed. However, the devices of the high frequency unavoidably encounter the problem of the processing etching uniformity due to sine waves generated from the electrodes 3 and 5.

For example, in order to acquire a high deposition rate and a high etching rate, the RF power-supply system must maintain the high plasma electron density by minimizing the loss of electrons caused by the plasma. However, electrons contained in the plasma of the RF power-supply system of the conventional plasma processing apparatus are emitted to the electrode (reference number 3 or 5) receiving the source RF power, so that the high plasma electron density cannot be maintained.

In order to solve the above-mentioned problem, the RF power-supply system additionally applies the bias RF power to the electrode (reference number 3 or 5) receiving the source RF power, so that it can effectively confine electrodes in the plasma and prevents the electrons from being emitted from the plasma. However, the RF power-supply system cannot certainly confine low-temperature electrodes of the plasma according to the variation of a semiconductor fabrication process.

### SUMMARY

Therefore, it is an aspect of the invention to provide a plasma processing apparatus and method for maximizing the plasma electron density in a plasma process in which the semiconductor substrate is processed using the plasma, so that it can increase the semiconductor processing rate.

It is another aspect of the invention to provide a plasma processing apparatus and method for applying a DC voltage to an electrode receiving a source RF power so as to confine electrons of the plasma, thereby maximizing the plasma electron density.

It is yet another aspect of the invention to provide a plasma processing apparatus and method for applying a pulse-format DC voltage, resulting in the prevention of the danger of etching the electrode receiving the source RF power. The etching of the electrode is caused by the electrons excessively accumulated in the plasma.

Additional aspects and/or advantages of the invention will be set forth in part in the description which follows and, in part, will be apparent from the description, or may be learned by practice of the invention.

In accordance with the invention, the above and/or other aspects can be achieved by the provision of a plasma processing apparatus including: a chamber which generates plasma to process a semiconductor substrate; upper and lower electrodes arranged in the chamber; a DC power-supply unit which applies a DC voltage to either one of the upper and lower electrodes; and a controller which adjusts a power ratio of the DC voltage applied from the DC power-supply unit to either one of the upper and lower electrodes.

The apparatus may further include: a RF power-supply unit for applying different RF powers to the upper and lower electrodes, wherein the RF power-supply unit includes a first RF power-supply unit for providing a source RF power, and a second RF power-supply unit for providing a bias RF power less than the source RF power.

Either one of the upper and lower electrodes may be an electrode receiving the source RF power.

The controller may control a duty ratio of the DC voltage applied to the electrode receiving the source RF power, so that it adjusts the power ratio of the DC voltage according to a pulse format.

The DC voltage may have a potential of −500V˜−3000V.

The duty ratio of the DC voltage may be 1%˜99%.

The DC voltage may have a pulse frequency of 10 Hz˜1000 KHz.

In accordance with another aspect of the present invention, there is provided a plasma processing method including: providing RF powers having different frequencies to upper and lower electrodes arranged in a chamber which processes a semiconductor substrate by generating plasma; providing a DC voltage to either one of the upper and lower electrodes; and adjusting a power ratio of the DC voltage provided from the DC power-supply unit to either one of the upper and lower electrodes, and performing a plasma processing.

The providing of the RF powers having different frequencies to the upper and lower electrodes may include: providing a source RF power to either one of the upper and lower electrodes; and providing a bias RF power less than the source RF power to the other one of the upper and lower electrodes.

The providing of the DC voltage to either one of the upper and lower electrodes may include providing the DC voltage to the electrode receiving the source RF power.

The adjusting of the power ratio of the DC voltage applied to either one of the upper and lower electrodes may include controlling a duty ratio of the DC voltage applied to the electrode receiving the source RF power, thereby adjusting the power ratio of the DC voltage according to a pulse format.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows a RF power-supply system of a conventional plasma processing apparatus;

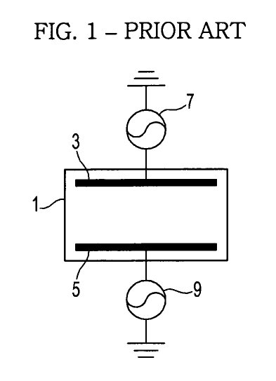

FIG. 2 is a block diagram illustrating a RF power-supply system according to the present invention;

FIG. 3 is a flow chart illustrating a plasma processing method according to the present invention;

FIG. 4 is a conceptual diagram illustrating a method for maximizing a plasma density of a plasma processing apparatus according to the present invention; and

FIG. 5 is a graph illustrating a variation of plasma density when a DC voltage is applied to a plasma processing apparatus according to the present invention.

### DETAILED DESCRIPTION OF THE EMBODIMENTS

Reference will now be made in detail to the embodiments of the present invention, examples of which are illustrated in the accompanying drawings, wherein like reference numerals refer to like elements throughout. The embodiments are described below to explain the present invention by referring to the figures.

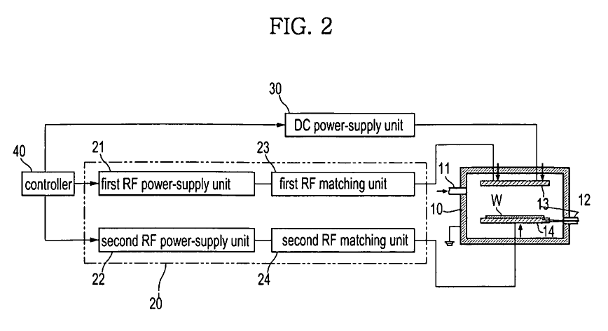

FIG. 2 is a block diagram illustrating a RF power-supply system according to the present invention.

Referring to FIG. 2, the plasma processing apparatus according to the present invention includes a chamber 10, a RF power-supply unit 20, a DC power-supply unit 30, and a controller 40.

The chamber 10 is a vacuum-status processing chamber in which the semiconductor fabrication process based on the plasma is conducted, and acts as a reactor for processing the etching process such as a wafer (W) used as the semiconductor substrate. In the chamber 10, a gas inlet 11 and a gas outlet 12 are formed, the gas supplied from the gas inlet 11 is excited into the plasma status by the RF power, so that the etching process of the wafer (W) is conducted.

The chamber 10 includes an upper electrode 13 receiving the source RF power and a lower electrode 14 receiving the bias RF power. The upper electrode 13 and the lower electrode 14 face each other.

The upper electrode 13 is a flat-type conductor which is located at an upper part of the chamber 10, so that it provides the chamber 10 with the source RF power, and the gas is excited into the plasma status.

The lower electrode 14 is located at a lower part of the chamber 10, and is arranged in parallel to the upper electrode 13. In the same manner as in the upper electrode 13, the lower electrode 14 acting as a flat-type conductor applies the bias RF power to the vacuum chamber 10 to excite the gas status into the plasma status, and a target object (e.g., wafer (W)) to be processed is placed on the lower electrode 14.

The RF power-supply unit 20 applies the RF power to the upper and lower electrodes 13 and 14 to excite the gas of the chamber into the plasma status. The RF power-supply unit 20 includes a first RF power-supply unit 21 for providing a first RF power (about 100 MHz) acting as the source RF power to the upper electrode 13, and a second RF power-supply unit 22 for providing a second RF power (about 13.56 MHz) acting as a low bias RF power less than the first RF power to the lower electrode 14. First and second RF matching units 23 and 24 are connected to the first and second RF power-supply units 21 and 22, respectively. The first and second RF matching units 23 and 24 perform the impedance matching, so that maximum powers of the first and second RF powers are applied to the upper and lower electrodes 13 and 14, respectively.

The DC power-supply unit 30 provides the DC voltage of −500V˜−3000V to the upper electrode 13 receiving the source RF power, so that it can confine electrons of the plasma. As a result, the DC power-supply unit 30 prevents electrons of the plasma from being emitted to the upper electrode 13. The DC power-supply unit 30 applies the pulse-format DC voltage to the upper electrode 13, so that the low-temperature electrons are stably confined, resulting in a maximized plasma electron density.

The controller 40 controls the power-supply ratio of the first and second RF power-supply units 21 and 22 to adjust a power ratio of the RF power applied to the upper and lower electrodes 13 and 14, and at the same time controls a frequency and duty ratio of the DC voltage applied to the upper electrode 13.

A plasma processing apparatus and method according to the present invention will hereinafter be described.

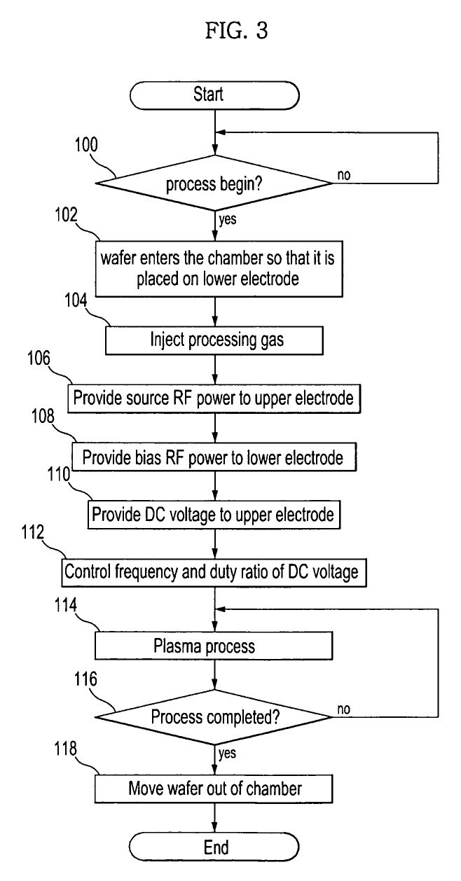

FIG. 3 is a flow chart illustrating a plasma processing method according to the present invention. A method for processing a single wafer (W) in a plasma process in which a semiconductor substrate is processed using the plasma will hereinafter be described.

Referring to FIG. 3, if the process begins at operation 100, the wafer (W) to be processed enters the chamber 10, so that it is placed on a lower electrode 14 at operation 102.

In this case, the processing gas is applied from the gas supplier (not shown) to the chamber 10 via the gas inlet 11, and is adjusted by the processing pressure at operation 104. The first RF power of 100 MHz indicating the source RF power generated from the first RF power-supply unit 21 is applied to the upper electrode 13 via the first RF matching unit 23, so that the gas injected in the chamber 10 is excited into the plasma status at operation 106.

A second RF power of 13.56 MHz indicating the bias RF power generated from the second RF power-supply unit 22 is applied to the lower electrode 14 via the second RF matching unit 24, so that the plasma is injected in the wafer (W) placed on the lower electrode 14. The plasma process of the wafer (W) begins using the ions and electrons generated from the plasma, so that the etching and depositing processes of the wafer (W) begin.

The first RF power indicating the source RF power is applied to the upper electrode 13, and the second RF power indicating the bias RF power is applied to the lower electrode 14, so that the DC voltage of −500V˜−3000V is applied from the DC power-supply unit 30 to the upper electrode 13 at operation 110.

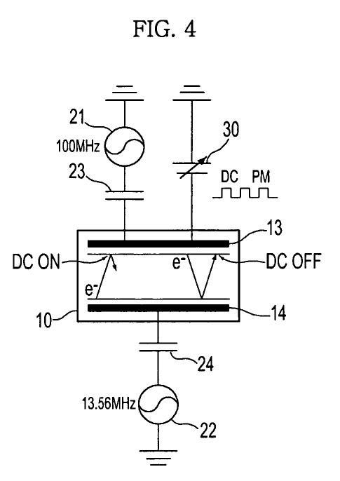

The DC voltage applied to the upper electrode 13 has the predetermined frequency of 10 Hz˜1000 KHz and the duty ratio of 1%˜99%, and is then configured in the form of a pulse at operation 112. In this case, upon receiving the pulse-type DC voltage, the plasma phenomenon can be conducted as shown in FIG. 4.

In FIG. 4, if the DC power with the frequency of 10 Hz˜1000 KHz is powered on according to the duty ratio determined by the controller 40, and a negative(−) voltage is applied to the upper electrode 13, most low-temperature electrons (e−) of the plasma do not exceed the negative (−) DC potential barrier, so that the electrons are confined in the plasma.

In this case, the high-temperature electrons having enough energy to overcome the negative (−) DC potential barrier can go over the potential barrier and then enter the upper electrode 13. However, this phenomenon is considered to be a desirable fact, because the high-temperature electrons may encounter excessive dissociation of the plasma gas or may increase the plasma potential.

If the DC power is powered off according to a predetermined duty ratio after it has been powered on, the electron emission phenomenon occurs, so that the low-temperature electrons (e−) confined in the negative(−) DC potential barrier are emitted to the upper electrode 13. This phenomenon is considered to be a desirable fact. If the low-temperature electrons (e−) confined in the plasma are excessively accumulated, the upper electrode 13 is in danger of etching the upper electrode 13, so that the negative (−) DC potential is switched off. As a result, the plasma processing apparatus prevents electrons from being excessively accumulated in the plasma space.

If the DC voltage applied to the upper electrode 13 is repeatedly switched on/off by a given frequency and a given duty ratio, the loss of electrons in the plasma is minimized, so that the plasma electron density is maximized, and at the same time the plasma electron density is maintained in a steady-state. As a result, the plasma process is stably conducted for a predetermined period of time at operation 114.

If the process is completed at operation 116, the wafer (W) moves out of the chamber 10, so that the wafer (W) processing is completed at operation 118.

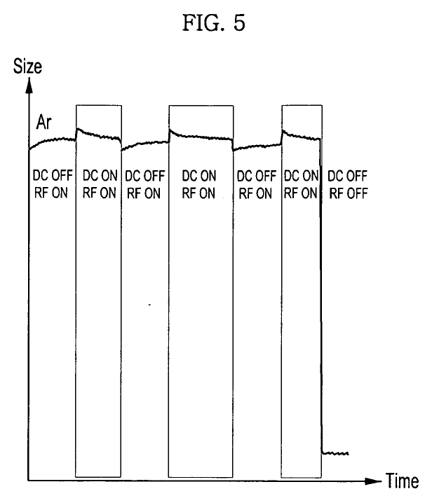

FIG. 5 is a graph illustrating a variation of plasma density when a DC voltage is applied to a plasma processing apparatus according to the present invention. If the RF power-supply system of the plasma processing apparatus applies the pulse-type DC voltage to the upper electrode 13, FIG. 5 shows the variation of the plasma density.

In FIG. 5, if the DC power is switched on, a sheath of the upper electrode 13 increases, and low-temperature electrons (e−) which have not overcome the energy gap, so that the plasma density unavoidably increases. Otherwise, if the DC power is switched off, the low-temperature electrons (e−) are emitted to the upper electrode 13, resulting in the reduction of the plasma density.

However, an average plasma density increases as compared to the case having no DC power, resulting in the implementation of a higher etching rate and a higher deposition rate.

As is apparent from the above description, the plasma processing apparatus and method according to the present invention applies a DC voltage to an electrode receiving the source RF power in a plasma process in which the semiconductor substrate is processed using the plasma, confines electrons of the plasma, so that it prevents the electrons from being emitted to the electrode receiving the source RF power, thereby maximizing the plasma electron density and increasing the semiconductor processing rate.

The plasma processing apparatus applies a pulse-format DC voltage to an electrode receiving the source RF power, and prevents the danger of etching the electrode receiving the source RF power, thereby stably increasing the semiconductor processing rate. The etching of the electrode is caused by the electrons excessively accumulated in the plasma.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A plasma processing apparatus comprising:
a chamber which generates plasma to process a semiconductor substrate;
upper and lower electrodes arranged in the chamber;
a DC power-supply unit which applies a DC voltage to either one of the upper and lower electrodes; and
a controller which adjusts a power ratio of the DC voltage applied from the DC power-supply unit to either one of the upper and lower electrodes.

2. The apparatus according to claim 1, further comprising a RF power-supply unit for applying different RF powers to the upper and lower electrodes,
wherein the RF power-supply unit includes a first RF power-supply unit for providing a source RF power, and a second RF power-supply unit for providing a bias RF power less than the source RF power.

3. The apparatus according to claim 2, wherein either one of the upper and lower electrodes is an electrode receiving the source RF power.

4. The apparatus according to claim 3, wherein the controller controls a duty ratio of the DC voltage applied to the electrode receiving the source RF power, so that it adjusts the power ratio of the DC voltage according to a pulse format.

5. The apparatus according to claim 4, wherein the DC voltage has a potential of −500V˜−3000V.

6. The apparatus according to claim 4, wherein the duty ratio of the DC voltage is 1%˜99%.

7. The apparatus according to claim 4, wherein the DC voltage has a pulse frequency of 10 Hz˜1000 KHz.

8. A plasma processing method comprising:
providing RF powers having different frequencies to upper and lower electrodes arranged in a chamber which processes a semiconductor substrate by generating plasma;
providing a DC voltage to either one of the upper and lower electrodes; and
adjusting a power ratio of the DC voltage provided from the DC power-supply unit to either one of the upper and lower electrodes, and performing a plasma processing.

9. The method according to claim 8, wherein the providing of the RF powers having different frequencies to the upper and lower electrodes includes:
providing a source RF power to either one of the upper and lower electrodes; and
providing a bias RF power less than the source RF power to the other one of the upper and lower electrodes.

10. The method according to claim 9, wherein the providing of the DC voltage to either one of the upper and lower electrodes includes providing the DC voltage to the electrode receiving the source RF power.

11. The method according to claim 10 wherein the adjusting of the power ratio of the DC voltage applied to either one of the upper and lower electrodes includes controlling a duty ratio of the DC voltage applied to the electrode receiving the source RF power, thereby adjusting the power ratio of the DC voltage according to a pulse format.

12. The method according to claim 11, wherein the DC voltage has a potential of −500V˜−3000V.

13. The method according to claim 11, wherein the duty ratio of the DC voltage is 1%˜99%.

14. The method according to claim 11, wherein the DC voltage has a pulse frequency of 10 Hz˜1000 KHz.

15. The method according to claim 9, wherein the source RF power is about 100 MHz.

16. The method according to claim 9, wherein the bias RF power is about 13.56 MHz.
